(19) United States
(12) Patent Application Publication
(10) Pub. No.: US 2024/0389289 A1
(43) Pub. Date: Nov. 21, 2024

(54) APPARATUS AND SYSTEM OF ELECTROMAGNETIC INTERFERENCE (EMI) SHIELDING

(71) Applicant: Intel Corporation, Santa Clara, CA (US)

(72) Inventors: Kari Mansukoski, Hillsboro, OR (US); Cody Kim Hougnon, Hillsboro, OR (US); Juha Paavola, Hillsboro, OR (US); Sami Markus Heinisuo, Dallas, OR (US); Sanna Mari Peurala, Kammenniemi (FI)

(73) Assignee: Intel Corporation, Santa Clara, CA (US)

(21) Appl. No.: 18/319,156

(22) Filed: May 17, 2023

(51) Int. Cl. H05K 9/00; G06F 1/16; H05K 1/02

(52) U.S. Cl. CPC H05K 9/0024; G06F 1/1656; H05K 1/0216

(57) ABSTRACT

For example, an apparatus may include an Electromagnetic Interference (EMI) shield, which may be configured to provide EMI shielding for electronic circuitry on a Printed Circuit Board (PCB). For example, the EMI shield may be configured to include an EMI shield lid; and an EMI shield connector to electrically couple the EMI shield lid to at least one tube on the PCB to provide a ground to the EMI shield lid via the at least one tube. For example, the EMI shield connector may be configured to maintain the EMI shield lid over the electronic circuitry on the PCB.

### TECHNICAL FIELD

Aspects described herein generally relate to apparatus and system of Electromagnetic Interference (EMI) shielding.

### BACKGROUND

An Electromagnetic Interference (EMI) shield may be configured to provide EMI shieling for one or more electronic components on a Printed Circuit Board (PCB).

### BRIEF DESCRIPTION OF THE DRAWINGS

For simplicity and clarity of illustration, elements shown in the figures have not necessarily been drawn to scale. For example, the dimensions of some of the elements may be exaggerated relative to other elements for clarity of presentation. Furthermore, reference numerals may be repeated among the figures to indicate corresponding or analogous elements. The figures are listed below.

FIG. 1 is a schematic block diagram illustration of an electronic device, in accordance with some demonstrative aspects.

FIG. 2 is a schematic block diagram illustration of an Electromagnetic Interference (EMI) shield configured to provide EMI shielding for electronic circuitry on a Printed Circuit Board (PCB), in accordance with some demonstrative aspects.

FIG. 3A is a schematic illustration of an EMI shield, and FIG. 3B is a schematic illustration of the EMI shield, while excluding a lid of the EMI shield, to illustrate assembly of the EMI shield on a PCB, in accordance with some demonstrative aspects.

FIG. 4 is a schematic illustration of a plurality of snaps of an EMI connector, in accordance with some demonstrative aspects.

FIG. 5A is a schematic illustration of an EMI shield at a detached state, and FIG. 5B is a schematic illustration of the EMI shield at an attached state, in accordance with some demonstrative aspects.

FIG. 6 is a schematic illustration of a graph depicting an EMI shielding effectiveness of an EMI shield versus frequency, in accordance with some demonstrative aspects.

FIG. 7A is a schematic illustration of a magnetic field (H-field) of electronic circuity, and FIG. 7B is a schematic illustration of the H-field of the electronic circuity when implementing an EMI shield, in accordance with some demonstrative aspects.

FIG. 8A is a schematic illustration of an Electric field (E-field) of electronic circuity, and FIG. 8B is a schematic illustration of the E-field of the electronic circuity when implementing an EMI shield, in accordance with some demonstrative aspects.

### DETAILED DESCRIPTION

In the following detailed description, numerous specific details are set forth in order to provide a thorough understanding of some aspects. However, it will be understood by persons of ordinary skill in the art that some aspects may be practiced without these specific details. In other instances, well-known methods, procedures, components, units and/or circuits have not been described in detail so as not to obscure the discussion.

Discussions herein utilizing terms such as, for example, “processing”, “computing”, “calculating”, “determining”, “establishing”, “analyzing”, “checking”, or the like, may refer to operation(s) and/or process(es) of a computer, a computing platform, a computing system, or other electronic computing device, that manipulate and/or transform data represented as physical (e.g., electronic) quantities within the computer's registers and/or memories into other data similarly represented as physical quantities within the computer's registers and/or memories or other information storage medium that may store instructions to perform operations and/or processes.

The terms “plurality” and “a plurality”, as used herein, include, for example, “multiple” or “two or more”. For example, “a plurality of items” includes two or more items.

References to “one aspect”, “an aspect”, “demonstrative aspect”, “various aspects” etc., indicate that the aspect(s) so described may include a particular feature, structure, or characteristic, but not every aspect necessarily includes the particular feature, structure, or characteristic. Further, repeated use of the phrase “in one aspect” does not necessarily refer to the same aspect, although it may.

As used herein, unless otherwise specified the use of the ordinal adjectives “first”, “second”, “third” etc., to describe a common object, merely indicate that different instances of like objects are being referred to, and are not intended to imply that the objects so described must be in a given sequence, either temporally, spatially, in ranking, or in any other manner.

Some aspects may be used in conjunction with various devices and systems, for example, a computing device, an electronic device, an electrical device, a User Equipment (UE), a Mobile Device (MD), a wireless station (STA), a Personal Computer (PC), a desktop computer, a mobile computer, a laptop computer, a notebook computer, a tablet computer, a handheld computer, a sensor device, an Internet of Things (IoT) device, a wearable device, a handheld device, a Personal Digital Assistant (PDA) device, a handheld PDA device, a vehicular device, a non-vehicular device, a mobile or portable device, a consumer device, a non-mobile or non-portable device, a wireless communication station, a wireless communication device, a wireless Access Point (AP), a wired or wireless router, a wired or wireless modem, a video device, an audio device, an audio-video (A/V) device, and the like.

Some aspects may be used in conjunction with devices and/or networks operating in accordance with existing IEEE 802.11 standards (including IEEE 802.11-2020 (IEEE 802.11-2020, IEEE Standard for Information Technology—Telecommunications and Information Exchange between Systems Local and Metropolitan Area Networks—Specific Requirements; Part 11: Wireless LAN Medium Access Control (MAC) and Physical Layer (PHY) Specifications, December 2020)) and/or future versions and/or derivatives thereof, devices and/or networks operating in accordance with existing cellular specifications and/or protocols, and/or future versions and/or derivatives thereof, units and/or devices which are part of the above networks, and the like.

Some aspects may be used in conjunction with one way and/or two-way radio communication systems, cellular radio-telephone communication systems, a mobile phone, a cellular telephone, a wireless telephone, a Personal Communication Systems (PCS) device, a PDA device which incorporates a wireless communication device, a mobile or portable Global Positioning System (GPS) device, a device which incorporates a GPS receiver or transceiver or chip, a device which incorporates an RFID element or chip, a Multiple Input Multiple Output (MIMO) transceiver or device, a Single Input Multiple Output (SIMO) transceiver or device, a Multiple Input Single Output (MISO) transceiver or device, a device having one or more internal antennas and/or external antennas, Digital Video Broadcast (DVB) devices or systems, multi-standard radio devices or systems, a wired or wireless handheld device, e.g., a Smartphone, a Wireless Application Protocol (WAP) device, or the like

Some aspects may be used in conjunction with one or more types of wireless communication signals and/or systems, for example, Radio Frequency (RF), Infra-Red (IR), Frequency-Division Multiplexing (FDM), Orthogonal FDM (OFDM), Orthogonal Frequency-Division Multiple Access (OFDMA), Spatial Divisional Multiple Access (SDMA), FDM Time-Division Multiplexing (TDM), Time-Division Multiple Access (TDMA), Multi-User MIMO (MU-MIMO), Extended TDMA (E-TDMA), General Packet Radio Service (GPRS), extended GPRS, Code-Division Multiple Access (CDMA), Wideband CDMA (WCDMA), CDMA 2000, single-carrier CDMA, multi-carrier CDMA, Multi-Carrier Modulation (MDM), Discrete Multi-Tone (DMT), Bluetooth®, Global Positioning System (GPS), Wi-Fi, Wi-Max, ZigBee™, Ultra-Wideband (UWB), Global System for Mobile communication (GSM), 2G, 2.5G, 3G, 3.5G, 4G, Fifth Generation (5G) mobile networks, 3GPP, Long Term Evolution (LTE), LTE advanced, Enhanced Data rates for GSM Evolution (EDGE), or the like. Other aspects may be used in various other devices, systems and/or networks.

The term “wireless device”, as used herein, includes, for example, a device capable of wireless communication, a communication device capable of wireless communication, a communication station capable of wireless communication, a portable or non-portable device capable of wireless communication, or the like. In some demonstrative aspects, a wireless device may be or may include a peripheral that may be integrated with a computer, or a peripheral that may be attached to a computer. In some demonstrative aspects, the term “wireless device” may optionally include a wireless service.

The term “communicating” as used herein with respect to a communication signal includes transmitting the communication signal and/or receiving the communication signal. For example, a communication unit, which is capable of communicating a communication signal, may include a transmitter to transmit the communication signal to at least one other communication unit, and/or a communication receiver to receive the communication signal from at least one other communication unit. The verb communicating may be used to refer to the action of transmitting or the action of receiving. In one example, the phrase “communicating a signal” may refer to the action of transmitting the signal by a first device, and may not necessarily include the action of receiving the signal by a second device. In another example, the phrase “communicating a signal” may refer to the action of receiving the signal by a first device, and may not necessarily include the action of transmitting the signal by a second device. The communication signal may be transmitted and/or received, for example, in the form of Radio Frequency (RF) communication signals, and/or any other type of signal.

As used herein, the term “circuitry” may refer to, be part of, or include, an Application Specific Integrated Circuit (ASIC), an integrated circuit, an electronic circuit, a processor (shared, dedicated or group), and/or memory (shared, Dedicated, or group), that execute one or more software or firmware programs, a combinational logic circuit, and/or other suitable hardware components that provide the described functionality. In some aspects, some functions associated with the circuitry may be implemented by, one or more software or firmware modules. In some aspects, circuitry may include logic, at least partially operable in hardware.

The term “logic” may refer, for example, to computing logic embedded in circuitry of a computing apparatus and/or computing logic stored in a memory of a computing apparatus. For example, the logic may be accessible by a processor of the computing apparatus to execute the computing logic to perform computing functions and/or operations. In one example, logic may be embedded in various types of memory and/or firmware, e.g., silicon blocks of various chips and/or processors. Logic may be included in, and/or implemented as part of, various circuitry, e.g. radio circuitry, receiver circuitry, control circuitry, transmitter circuitry, transceiver circuitry, processor circuitry, and/or the like. In one example, logic may be embedded in volatile memory and/or non-volatile memory, including random access memory, read only memory, programmable memory, magnetic memory, flash memory, persistent memory, and the like. Logic may be executed by one or more processors using memory, e.g., registers, stuck, buffers, and/or the like, coupled to the one or more processors, e.g., as necessary to execute the logic.

The term “antenna”. as used herein, may include any suitable configuration, structure and/or arrangement of one or more antenna elements, components, units, assemblies and/or arrays. In some aspects, the antenna may implement transmit and receive functionalities using separate transmit and receive antenna elements. In some aspects, the antenna may implement transmit and receive functionalities using common and/or integrated transmit/receive elements. The antenna may include, for example, a phased array antenna, a single element antenna, a set of switched beam antennas, and/or the like.

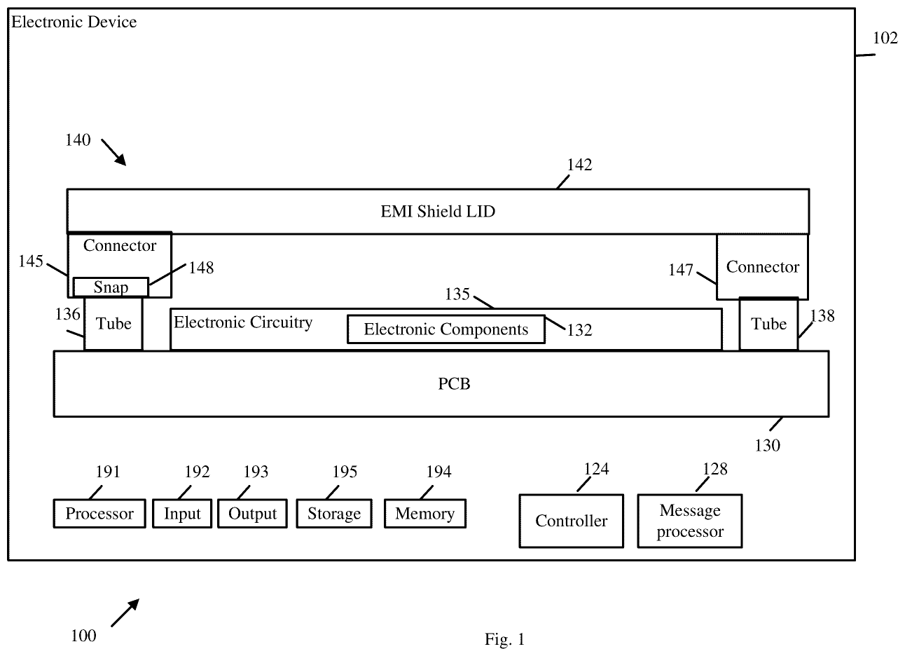

Reference is now made to FIG. 1, which schematically illustrates a block diagram of an electronic device 102, in accordance with some demonstrative aspects.

In some demonstrative aspects, electronic device 102 may include an electrical device, a mobile device, a non-mobile device, a computing device, a wireless communication device, or the like.

In some demonstrative aspects, device 102 may include, for example, a UE, a mobile phone, an MD, a PC, a desktop computer, a mobile computer, a laptop computer, an Ultrabook™ computer, a notebook computer, a tablet computer, a server computer, a handheld computer, an Internet of Things (IoT) device, a sensor device, a handheld device, a wearable device, a PDA device, a handheld PDA device, an on-board device, an off-board device, a hybrid device (e.g., combining cellular phone functionalities with PDA device functionalities), a consumer device, an electrical device, a vehicular device, a non-vehicular device, a mobile or portable device, a non-mobile or non-portable device, a mobile phone, a cellular telephone, a PCS device, a PDA device which incorporates a wireless communication device, a mobile or portable GPS device, a relatively small computing device, a non-desktop computer, a “Carry Small Live Large” (CSLL) device, an Ultra Mobile Device (UMD), an Ultra Mobile PC (UMPC), a Mobile Internet Device (MID), or the like.

In some demonstrative aspects, device 102 may include, for example, one or more of a processor 191, an input unit 192, an output unit 193, a memory unit 194, and/or a storage unit 195. Device 102 may optionally include other suitable hardware components and/or software components. In some demonstrative aspects, some or all of the components of one or more of device 102 may be enclosed in a common housing or packaging, and may be interconnected or operably associated using one or more wired or wireless links. In other aspects, components of one or more of device 102 may be distributed among multiple or separate devices.

In some demonstrative aspects, processor 191 may include, for example, a Central Processing Unit (CPU), a Digital Signal Processor (DSP), one or more processor cores, a single-core processor, a dual-core processor, a multiple-core processor, a microprocessor, a host processor, a controller, a plurality of processors or controllers, a chip, a microchip, one or more circuits, circuitry, a logic unit, an Integrated Circuit (IC), an Application-Specific IC (ASIC), or any other suitable multi-purpose or specific processor or controller. Processor 191 may execute instructions, for example, of an Operating System (OS), e.g., a vehicular operating system, of device 102 and/or of one or more suitable applications.

In some demonstrative aspects, input unit 192 may include, for example, a touch-screen, a touch-pad, a track-ball, a stylus, a microphone, or other suitable pointing device or input device. Output unit 193 includes, for example, a monitor, a screen, a touch-screen, a flat panel display, a Light Emitting Diode (LED) display unit, a Liquid Crystal Display (LCD) display unit, one or more audio speakers or earphones, or other suitable output devices.

In some demonstrative aspects, memory unit 194 includes, for example, a Random Access Memory (RAM), a Read Only Memory (ROM), a Dynamic RAM (DRAM), a Synchronous DRAM (SD-RAM), a flash memory, a volatile memory, a non-volatile memory, a cache memory, a buffer, a short term memory unit, a long term memory unit, or other suitable memory units. Storage unit 195 may include, for example, a hard disk drive, a disk drive, a solid-state drive (SSD), and/or other suitable removable or non-removable storage units. Memory unit 194 and/or storage unit 195, for example, may store data processed by device 102.

In some demonstrative aspects, electronic device 102 may include a controller 124 configured to control one or more functionalities, components, devices, and/or elements of electronic device 102.

In some demonstrative aspects, controller 124 may be configured to perform and/or to trigger, cause, instruct and/or control device 102 to perform one or more functionalities, operations and/or procedures, and/or to perform one or more communications, to generate and/or communicate one or more messages and/or transmissions.

In some demonstrative aspects, controller 124 may configured to control device 102, and/or to process one or parameters, attributes and/or information from device 102.

In some demonstrative aspects, controller 124 may be configured process the one or parameters, attributes and/or information of device 102.

In some demonstrative aspects, controller 124 may include, or may be implemented, partially or entirely, by circuitry and/or logic, e.g., one or more processors including circuitry and/or logic, memory circuitry and/or logic. Additionally or alternatively, one or more functionalities of controller 124 may be implemented by logic, which may be executed by a machine and/or one or more processors, e.g., as described below.

In one example, controller 124 may include circuitry and/or logic, for example, one or more processors including circuitry and/or logic, to cause, trigger and/or control a wireless device, e.g., device 102, and/or a wireless station, e.g., a wireless STA implemented by device 102, to perform one or more operations, communications and/or functionalities, e.g., as described herein. In one example, controller 124 may include at least one memory, e.g., coupled to the one or more processors, which may be configured, for example, to store, e.g., at least temporarily, at least some of the information processed by the one or more processors and/or circuitry, and/or which may be configured to store logic to be utilized by the processors and/or circuitry.

In some demonstrative aspects, device 102 may include a message processor 128 configured to generate, process and/or access one or more messages communicated by device 102.

In one example, message processor 128 may be configured to generate one or more messages to be transmitted by device 102, and/or message processor 128 may be configured to access and/or to process one or more messages received by device 102, e.g., as described below.

In some demonstrative aspects, message processor 128 may include, or may be implemented, partially or entirely, by circuitry and/or logic, e.g., one or more processors including circuitry and/or logic, memory circuitry and/or logic.

Additionally or alternatively, one or more functionalities of message processor 128 may be implemented by logic, which may be executed by a machine and/or one or more processors, e.g., as described below.

In some demonstrative aspects, at least part of the functionality of message processor 128 may be implemented as part of controller 124.

In other aspects, the functionality of message processor 128 may be implemented as part of any other element of device 102.

In some demonstrative aspects, at least part of the functionality of controller 124 and/or message processor 128 may be implemented by an integrated circuit, for example, a chip, e.g., a System on Chip (SoC). For example, the chip or SoC may include one or more elements of controller 124, and/or one or more elements of message processor 128. In one example, controller 124 and message processor 128 may be implemented as part of the chip or SoC.

In other aspects, controller 124 and/or message processor 128 may be implemented by one or more additional or alternative elements of device 102.

In some demonstrative aspects, device 102 may include a Printed Circuit Board (PCB) 130, e.g., as described below.

In some demonstrative aspects, device 102 may include electronic circuitry 135 on the PCB 130, e.g., as described below.

In some demonstrative aspects, electronic circuitry 135 may include one or more electronic components 132 (also referred to as “electrical components”).

In some demonstrative aspects, the electronic components 132 may include one or more electronic components, devices, and/or elements, one or more electrical components, devices, and/or elements, and/or any other components, devices, and/or elements, e.g., as described below.

In some demonstrative aspects, the electronic components 132 may one or more active components, for example, transistors, diodes, Integrated Circuits (IC), chips, SoCs, programable devices, or the like.

In some demonstrative aspects, the electronic components 132 may one or more passive components, for example, resistors, capacitors, integrated passive devices, or the like.

In one example, electronic circuitry 135 may include an electronic component 132 including a chip, an IC and/or an SoC. For example, electronic circuitry 135 may include one or more components of controller 124 and/or message processor 128.

In another example, electronic circuitry 135 may include one or more components of a memory. For example, electronic circuitry 135 may include electronic components 132 including one or more components of memory 194.

In another example, electronic circuitry 135 may include one or more components of a storage. For example, electronic circuitry 135 may include electronic components 132 including one or more components of storage 195.

In another example, electronic circuitry 135 may include one or more radio components of a radio. In one example, electronic circuitry 135 may include electronic components 132 including one or more Radio Frequency (RF) elements, circuitry and/or logic; baseband elements, circuitry and/or logic; modulation elements, circuitry and/or logic; demodulation elements, circuitry and/or logic; amplifiers; analog to digital and/or digital to analog converters; filters; and/or the like.

In some demonstrative aspects, the electronic circuitry 135 may include one or more Surface Mounted Devices (SMDs).

In one example, electronic circuitry 135 may include one or more SMDs mounted, e.g., directly, onto a surface of the PCB 130, for example, according to a Surface-Mount Technology (SMT), and/or any other additional or alternative technology and/or mechanism.

In another example, electronic circuitry 135 may include one or more SMDs mounted onto, placed directly onto, or attached to, the PCB 130, e.g., by soldering. For example, soldering the SMDs to the PCB 130 may provide a technical solution to both electrically connect and mechanically attach the SMDs to the PCB 130.

In other aspects, electronic circuitry 135 may include any other additional or alternative mounted devices, which may be attached to, mounted on, and/or coupled to, PCB 130 according to any other additional or alternative technology and/or mechanism.

In some demonstrative aspects, the SMDs may include, for example, transistors, resistors, capacitors, ICs, chips, SoCs, and/or the like.

In some demonstrative aspects, electronic circuitry 135 may include any other additional and/or alternative type of electronic circuitry, and/or electronic components 132 may include any other additional or alternative type of electronic components.

In some demonstrative aspects, PCB 130 may be configured to mechanically support and/or electrically connect between the electronic components 132 and one or more other elements of device 102, e.g., as described below.

In one example, PCB 130 may be configured to mechanically support and/or electrically connect the electronic components 132 to one or more other elements of device 102, for example, using conductive tracks, signal traces, pads and/or any other mechanism.

In some demonstrative aspects, device 102 may include at least one tube 136, which may be mounted to and/or connected to PCB 130, e.g., as described below.

In some demonstrative aspects, tube 136 may be soldered to the PCB 130, e.g., as described below. In other aspects, tube 136 may be attached to, connected to, or mounted to, PCB 130 using any other additional or alternative mechanism and/or technique.

In some demonstrative aspects, the tube 136 may include a cylindrical tube or a circular tube, e.g., having a circular shape, an oval shape, or any other cylindrical shape.

In some demonstrative aspects, the tube 136 may include a rectangular tube or a square tube, e.g., having a rectangular shape or a square shape.

In other aspects, the tube 136 may include any other tube having any other shape.

In some demonstrative aspects, tube 136 may include a solid metal shell.

In other aspect, tube 136 may include any other type of shell.

In some demonstrative aspects, tube 136 may include a cable having a solid metal shell.

In some demonstrative aspects, tube 136 may include a metallic tube, which may be soldered onto PCB 130. For example, a metallic outer surface of tube 136 may be connected to PCB 130, for example, via solder pads.

In some demonstrative aspects, tube 136 may include, or may be, a rigid solder down cable or tube, e.g., as described below.

In one example, light mobile electrical devices, e.g., device 102, may utilize solder down cables, e.g., implemented by tube 136, to prevent signal loss, for example, due to standard substrate materials on motherboard.

In some demonstrative aspects, the solder down cable may be stiff and rigid, for example, due to a solid metal shell of the solder down cable.

In one example, the solder down cable may be implemented on the motherboard, for example, to prevent signal loss, e.g., in case of long sensitive traces on PCB 130.

In another example, the solder down cable may be used to transfer any other signal or power, e.g., which may be utilized by one or more components or devices on PCB 130.

In some demonstrative aspects, the tube 136 may be implemented as a separate element, for example, to cover a cable inside the tube 136.

In some demonstrative aspects, tube 136 may be utilized to transfer signals and/or power on and/or across PCB 130, for example to provide battery voltage and/or an antenna trace, e.g., where needed.

In some demonstrative aspects, tube 136 may be utilized to transfer signals to one or more electronic components 132 of the electronic circuitry 135 and/or to any other additional or alternative components on PCB 130.

In one example, the cable in tube 136 may carry an electrical signal, e.g., an RF antenna signal and/or any other electrical signal. For example, the electrical signal may be carried inside the tube 136, for example, in such way that the electrical signal may be isolated from a grounded connection on an outer layer of the tube 136.

In some demonstrative aspects, tube 136 may be utilized to transfer electric power to one or more electronic components 132 of electronic circuitry 135 and/or to any other additional or alternative components on PCB 130.

In one example, the cable in tube 136 may be configured to carry a power supply. For example, the power supply may be carried inside the tube 136, for example, in such way that the power supply may be isolated from the grounded connection on the outer layer of the tube 136.

In some demonstrative aspects, the electrical signal and/or the power supply may enter from one end of the tube 136 and may exist from another end of the tube 136.

In some demonstrative aspects, an inner surface of tube 136 may be configured to carry one or more coax cables, which may transfer RF signals, power supply, and/or any other signal to be routed over PCB 130, e.g., from one side to another side of PCB 130.

In some demonstrative aspects, device 102 may include one or more Electromagnetic Interference (EMI) shields, which may be configured, for example, to limit electromagnetic and/or Radio-Frequency (RF) Interference (RFI) within the device 102 and/or between the device 102 and the external world.

In some demonstrative aspects, device 102 may include an EMI shield 140 configured to provide EMI shielding for the electronic circuitry 135 on the PCB 130, e.g., as described below.

In some demonstrative aspects, EMI shield 140 may be configured to provide EMI shielding at least to frequencies in a frequency range between about 2 Gigahertz (GHz) and about 10 GHz, e.g., as described below.

In some demonstrative aspects, the EMI shield 140 may be configured to provide the EMI shielding at least to frequencies in a frequency range between about 2.2 GHz and about 8 GHz, e.g., as described below.

In some demonstrative aspects, the EMI shield 140 may be configured to provide the EMI shielding at least to frequencies in a frequency range between about 2.4 GHz and about 7.2 GHz, e.g., as described below.

In other aspects, the EMI shield 140 may be configured to provide the EMI shielding to frequencies in any other frequency range.

In some demonstrative aspects, the EMI shield 140 may be configured to provide the EMI shielding at frequencies of up to at least about 1 GHz, e.g., as described below.

In some demonstrative aspects, the EMI shield 140 may be configured to provide the EMI shielding at frequencies of up to at least about 2 GHz, e.g., as described below.

In some demonstrative aspects, the EMI shield 140 may be configured to provide the EMI shielding at frequencies of up to at least about 2.4 GHz, for example, for wireless communication implementations utilizing a 2.4 GHz frequency band, e.g., as described below.

In some demonstrative aspects, the EMI shield 140 may be configured to provide the EMI shielding at frequencies of up to at least about 3 GHz, e.g., as described below.

In some demonstrative aspects, the EMI shield 140 may be configured to provide the EMI shielding at frequencies of up to at least about 6 GHz, for example, for wireless communication implementations utilizing a 5 GHz frequency band, e.g., as described below.

In some demonstrative aspects, the EMI shield 140 may be configured to provide the EMI shielding at frequencies of up to at least about 7.2 GHz, for example, for wireless communication implementations utilizing a 6 GHz frequency band, e.g., as described below.

In some demonstrative aspects, the EMI shield 140 may be configured to provide the EMI shielding at frequencies of up to at least about 8 GHz, e.g., as described below.

In some demonstrative aspects, the EMI shield 140 may be configured to provide the EMI shielding at frequencies of up to at least about 10 GHz, e.g., as described below.

In some demonstrative aspects, the EMI shield 140 may be configured to provide the EMI shielding for any suitable other frequencies.

In some demonstrative aspects, EMI shield 140 may include an EMI shield lid 142, e.g., as described below.

In some demonstrative aspects, EMI shield lid 142 may be disposed over the electronic circuitry 135 on the PCB 130, e.g., as described below.

In some demonstrative aspects, EMI shield lid 142 may be configured to cover the electronic circuitry 135 on the PCB 130, e.g., as described below.

In some demonstrative aspects, EMI shield 140 may include an EMI shield connector 145, e.g., as described below.

In some demonstrative aspects, the EMI shield connector 145 may be configured to connect the EMI shield lid 142 to at least one tube, e.g., including tube 136, on the PCB 130, e.g., as described below.

In some demonstrative aspects, EMI shield connector 145 may be configured to electrically couple the EMI shield lid 142 to the at least one tube on the PCB 130, e.g., tube 136, for example, to provide a ground to the EMI shield lid 142, for example, via the at least one tube 136, e.g., as described below.

In some demonstrative aspects, the EMI shield connector 145 may be configured to ground the EMI shield lid 142 via the tube 136, e.g., as described below.

In some demonstrative aspects, the EMI shield connector 145 may be configured to maintain the EMI shield lid 142 over the electronic circuitry 135 on the PCB 130, e.g., as described below.

In some demonstrative aspects, EMI shield 140 may be configured to use tube 136 as an EMI fence of EMI shield 140, e.g., as described below.

In some demonstrative aspects, EMI shield 140 may be configured to use tube 136 as an EMI shield connection, e.g., as described below.

In some demonstrative aspects, EMI shield 140 may be configured to provide a technical solution to efficiently implement an EMI shielding structure having a an EMI shield fence, which may be provided by one or more tubes 136, e.g., stiff solder down cables and/or any other cables or tubes, which may already be used in customer co-engineering projects, e.g., as described below.

In some demonstrative aspects, EMI shield 140 may be configured to provide a technical solution, in which tube 136 may be used as an EMI shield fence. For example, tube 136 may have a diameter of at least 1 millimeter (mm), which may provide a sufficient height for an EMI shield side wall, e.g., as described below.

In some demonstrative aspects, EMI shield 140 may be configured to utilize tube 136 as part of an EMI shield structure of EMI shield 140, e.g., as described below.

In some demonstrative aspects, EMI shield 140 may be configured to utilize an EMI shield structure, which may be formed by a combination of the tube 136 and the EMI shield lid 142, for example, to provide a technical solution to save area on PCB 130, e.g., as described below.

In one example, a tube implemented on a PCB, e.g., tube 136, may take up an area of, for example, at least 1 mm pad size, and a keep out zone on board of PCB 130. For example, at least part of this area of the PCB may be utilized as part of an EMI shield attachment of EMI shield 140, for example, to provide a technical solution to save area on PCB 130, e.g., as described below.

In some demonstrative aspects, EMI shield 140 may be configured to utilize the tube 136 as part of the EMI shield structure, for example, to provide a technical solution to save area on PCB 130 compared, for example, to a PCB area, which would have been required by implementations using a separate soldered EMI fence for EMI shield connection, e.g., which may be separate from the solder down tubes.

In one example, these implementations may require more parts, e.g., fences of an EMI shield, for example, in addition to the solder down tubes.

In another example, these implementations may utilize a bigger X-Y board space.

In some demonstrative aspects, EMI shield 140 may be configured to provide a technical solution to save on the board X-Y space.

In one example, EMI shield 140 may be configured to provide a technical solution to support an EMI shield utilizing a smaller board size and, accordingly, may provide more space for other elements, for example, a battery, and/or may extend a battery life.

In some demonstrative aspects, EMI shield 140 may be configured to utilize two or more tubes on two or more sides of the EMI shield lid 142, e.g., as described below.

For example, EMI shield 140 may be configured to utilize two tubes 136 as fences of the EMI shield 140, e.g., on two sides of EMI shield lid 142, e.g., as described below. According to this example, a space of, for example, 3-4 mm, may be saved on PCB 130, for example, compared to an implementation of a solder down EMI shield, which may be separate from the cables.

In some demonstrative aspects, EMI shield 140 may be configured to provide a technical solution to support implementation of Manufacturing Units (MU), e.g., M/U Stock-Keeping Units (SKUs), having a narrow board.

In some demonstrative aspects, EMI shield 140 may be configured to provide a technical solution to support EMI shielding for substantially any suitable electrical device, for example, in cases where a tube and an EMI shield are to be located on a narrow area on a PCB, e.g., as described below.

In some demonstrative aspects, EMI shield 140 may be configured to utilize the at least one tube 136, for example, to provide a technical solution to support a reduction, e.g., of about 7-10%, in the PCB area for EMI shielding, e.g., as described below.

In some demonstrative aspects, EMI shield 140 may be configured to provide a technical solution to support manufacturing of units having a narrow board, for example, by saving PCB area, e.g., as described below.

In some demonstrative aspects, EMI shield 140 may be configured to provide a technical solution to support EMI shielding, for example, even without a dedicated EMI fence, e.g., as described below.

In some demonstrative aspects, EMI shield 140 may be configured to provide a technical solution to connect the EMI shield lid 142 to tube 136, e.g., a coaxial cable or a separate tube, in a manner which may avoid the implementation of a dedicated SMT EMI fence, e.g., as described below.

In some demonstrative aspects, EMI shield 140 may be configured to provide a technical solution to ground the EMI shield lid 142 to the PCB 130, for example, through pads of tube 136, which may be soldered to PCB 130, e.g., as described below.

In some demonstrative aspects, configuring the EMI shield 140 to utilize the tube 136 as a EMI shield fence may provide a technical solution to support a reduce X-Y size of the Emi shield. Accordingly, the EMI shield 140 may provide a technical solution to support freeing up more space on the PCB 130, for example, to allow more space for other elements on the PCB 130, e.g., a battery and/or any other components, e.g., as described below.

In some demonstrative aspects, configuring the EMI shield 140 to utilize the tube 136 as a EMI shield fence may provide a technical solution to support reduction in the number of components for EMI shielding. The ability to configure EMI shield 140 using a reduced number of components may provide reduced cost and/or improved sustainability.

In some demonstrative aspects, EMI shield 140 may be configured to provide a technical solution to support a cheaper EMI shield construction, for example, compared to EMI shield implementations utilizing a dedicated and/or separate Emi shield fence, e.g., as described below.

In some demonstrative aspects, EMI shield 140 may be configured to implement one or more detachable and/or removable components, e.g., a detachable and/or removable EMI shield lid 142, for example, to provide a technical solution to support easy access to and/or reparability of the one or more electronic components 132, e.g., as described below.

In some demonstrative aspects, the EMI shield connector 145 may extend along at least one side of the EMI shield lid 142, e.g., as described below.

In some demonstrative aspects, EMI shield connector 145 may be configured to form with the at least one tube 136 an EMI shield fence between the EMI shield lid 142 and the PCB 130, e.g., as described below.

In some demonstrative aspects, the EMI shield connector 145 may be configured to form the EMI shield fence along at least one side of the EMI shield lid 142, e.g., as described below.

In some demonstrative aspects, the EMI shield connector 145 may be configured to ground the EMI shield lid 142 via a solder between the tube 136 and the PCB 130, e.g., as described below.

In some demonstrative aspects, EMI shield 140 may include an EMI shield fence disposed between the EMI shield lid 142 and the PCB 130, e.g., as described below.

For example, the EMI shield fence may be formed with the EMI shield connector 146 and the at least one tube 136, e.g., as described below.

For example, the EMI shield fence may be formed along at least one side of the EMI shield lid 142 with the EMI shield connector 145.

In some demonstrative aspects, a shape of the EMI shield connector 145 may be configured, for example, based on a shape of an outer surface of the tube 136, e.g., as described below.

In some demonstrative aspects, the EMI shield connector 145 may include a shape based on a shape of an outer surface of the at least one tube 136, e.g., as described below.

In some demonstrative aspects, a shape of the EMI shield connector 145 may be configured, for example, to fit over the outer surface of the tube 136, e.g., as described below.

In some demonstrative aspects, a shape of the EMI shield connector 145 may be configured, for example, to cover the outer surface of the tube 136, e.g., as described below.

In some demonstrative aspects, a shape of the EMI shield connector 145 may be configured, for example, to fit tightly over the outer surface of the tube 136, for example, without substantially any space or openings, e.g., as described below.

In some demonstrative aspects, a shape of the EMI shield connector 145 may be configured, for example, to connect the tube 136 to the EMI shield lid 142, for example, without substantially any gaps between the tube 136 and the EMI shield lid 142, e.g., any gaps which may allow EMI to pass through EMI shield 140.

In some demonstrative aspects, a shape of the EMI shield connector 145 may be configured to connect the EMI shield lid 142 to the tube 136, for example, to form an EMI shielding structure to shield the electronic circuitry 135 from EMI, e.g., as described below.

In some demonstrative aspects, a shape of the EMI shield connector 145 may be configured to connect the EMI shield lid 142 to the tube 136, for example, to form an EMI shielding structure to substantially completely surround the electronic circuitry 135, e.g., as described below.

In some demonstrative aspects, the EMI shield connector 145 may include at least one snap 148 configured to snap over the tube 136, e.g., as described below.

In some demonstrative aspects, the snap 148 may include a tube-engagement surface configured to engage and/or capable of engaging with an outer surface of the tube 136, e.g., as described below.

In some demonstrative aspects, a shape of the tube-engagement surface may be configured, for example, based on a shape of the outer surface of the at least one tube 136, e.g., as described below.

In some demonstrative aspects, the tube-engagement surface may include a shape based on a shape of the outer surface of the at least one tube 136, e.g., as described below.

In some demonstrative aspects, the EMI shield connector 145 may include may include a plurality of snaps 148 along at least one side of the EMI shield lid 142, e.g., as described below.

In some demonstrative aspects, a distance between two adjacent snaps 148 may be less than 2 millimeter (mm), e.g., as described below.

In some demonstrative aspects, the distance between two adjacent snaps 148 may be less than 1.5 mm, e.g., as described below.

In some demonstrative aspects, the distance between two adjacent snaps 148 may be less than 1.2 mm, e.g., as described below.

In some demonstrative aspects, the distance between two adjacent snaps 148 may be less than 1.1 mm, e.g., as described below.

In some demonstrative aspects, the distance between two adjacent snaps 148 may be less than 1 mm, e.g., as described below.

In other aspects, the plurality of snaps 148 may be implemented with any other distance between two adjacent snaps, for example, based on a frequency range for EMI shielding, a level of EMI shielding, and/or any other criteria.

In some demonstrative aspects, the snap 148 may include a single snap along at least one side of the EMI shield lid 142, e.g., as described below.

In one example, the snap 148 may be configured to connect over the tube 136, for example, along an entire length of the tube 136 connected to the EMI shield lid 142, e.g., without substantially any gaps.

In some demonstrative aspects, the EMI shield 140 may include a first EMI shield connector on a first side of the EMI shield lid 142, for example, to connect and/or electrically couple the EMI shield lid 142 to a first tube on the PCB 130, e.g., as described below.

In some demonstrative aspects, EMI shield 140 may include a second EMI shield connector on a second side of the EMI shield lid 142, for example, to connect and/or electrically couple the EMI shield lid 142 to a second tube on the PCB 130, e.g., as described below.

In some demonstrative aspects, the first side of the EMI shield lid 142 may be opposite to the second side of the EMI shield lid 142, e.g., as described below.

In other aspects, the second side of the EMI shield lid 142 may include any other side of the EMI shield lid 142, e.g., other than the first side.

In some demonstrative aspects, EMI shield 140 may include EMI shield connector 145 on a first side of the EMI shield lid 142, for example, to connect the EMI shield lid 142 to tube 136 on the PCB 130, e.g., as described below.

In some demonstrative aspects, EMI shield 140 may include an EMI shield connector 147 on a second side of the EMI shield lid 142, for example, to connect the EMI shield lid 142 to a second tube 138 on the PCB 130, e.g., as described below.

In some demonstrative aspects, shield 140 may include one or more EMI shield connectors on one or more sides of the EMI shield lid 142, for example, to connect the EMI shield lid 142 to one or more respective tubes.

In some demonstrative aspects, shield 140 may include one or more EMI shield fences on one or more other sides of the EMI shield lid 142, for example, to connect the one or more other sides of the EMI shield lid 142 to the PCB 130.

In one example, shield 140 may include EMI shield connector 145 to connect the first side of EMI shield lid 142 to tube 136, EMI shield connector 147 to connect the second side of EMI shield lid 142 to tube 138, and two EMI shield fences to connect two other respective sides of the EMI shield lid 142 to PCB 130, for example, to form an EMI shielding structure surrounding the electronic circuitry 135.

In some demonstrative aspects, EMI shield connector 145 may include a detachable connector configured to detachably connect and/or couple the EMI shield lid 142 to the tube 136, e.g., as described below.

In some demonstrative aspects, the detachable connector may be configured to electrically decouple the EMI shield lid 142 from the at least one tube 136, e.g., as described below.

In some demonstrative aspects, EMI shield 140 may be configured to provide an EMI a shielding solution utilizing an outer surface of tube 136, which may be grounded on PCB 130, e.g., via solder pads, for example, to firm an EMI shield fence.

In some demonstrative aspects, EMI shield 140 may be configured to utilize the outer surface of tube 136 to provide a continuous fence to shield electronic circuit 135.

In some demonstrative aspects, EMI shield 140 may be configured to utilize the outer surface of tube 136 as a ground connection for EMI shield lid 142 to PCB 130, e.g., via solder pads connecting tube 136 to PCB 130.

In some demonstrative aspects, EMI shield 140 may be configured to utilize the outer surface of tube 136 to provide multiple connection points, e.g., reliable multiple connection points, for one or more snaps 148, for example, to ground the EMI shield lid 142 via the snaps 148, the outer surface of tube 136 and the solder pads connecting tube 136 to PCB 130.

In some demonstrative aspects, EMI shield 140 may be configured to utilize the outer surface of tube 136 to act as a shield for signals running inside tube 136.

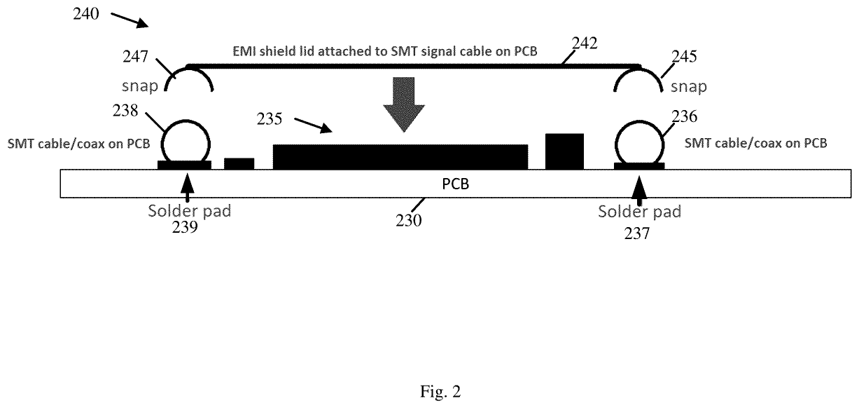

Reference is made to FIG. 2, which schematically illustrates an EMI shield 240 configured to provide EMI shielding for electronic circuitry 235 on a PCB 230, in accordance with some demonstrative aspects. For example, EMI shield 140 (FIG. 1) may include one or more elements of EMI shield 240, and/or may perform one or more functionalities of EMI shield 240.

In some demonstrative aspects, as shown in FIG. 2, EMI shield 240 may include an EMI shield lid 242 configured to cover the electronic circuitry 235 on the PCB 230.

In some demonstrative aspects, as shown in FIG. 2, the EMI shield 240 may include a first EMI shield connector 245 on a first side of the EMI shield lid 242, for example, to connect the EMI shield lid 242 to a tube 236 on the PCB 230.

In some demonstrative aspects, the EMI shield 240 may include a second EMI shield connector 247 on the second side of the EMI shield lid 242, for example, to connect the EMI shield lid 242 to a second tube 238 on the PCB.

In some demonstrative aspects, as shown in FIG. 2, the first side of the EMI shield lid 242 may be opposite to the second side of the EMI shield lid 242.

In some demonstrative aspects, as shown in FIG. 2, the EMI shield connector 245 may be configured to ground the EMI shield lid 242 to the PCB 230, for example, via the tube 236 and a first solder pad 237, e.g., between tube 236 and PCB 230.

In some demonstrative aspects, as shown in FIG. 2, the EMI shield connector 247 may be configured to ground the EMI shield lid 242 to the PCB 230, for example, via the tube 238 and a second solder pad 239, e.g., between tube 238 and PCB 230.

In some demonstrative aspects, the EMI shield connector 245 may include a detachable connector, which may be configured to detachably connect the EMI shield lid 242 to the tube 236.

In some demonstrative aspects, the EMI shield connector 247 may include a detachable connector, which may be configured to detachably connect the EMI shield lid 242 to the tube 238.

In some demonstrative aspects, the EMI shield connector 245 may include a snap configured to snap over the tube 236.

In some demonstrative aspects, as shown in FIG. 2, a shape of the snap of the EMI shield connector 245 may be configured to conform to a shape of the outer surface of the tube 236.

In one example, snap 245 may be configured as a single, continuous, snap element, which may be configured to extend along substantially an entire first side of the EMI shield lid 242, e.g., as described below.

In one example, snap 245 may be configured to include a plurality of snap elements, which may be configured to snap over different portions of the tube 236, e.g., as described below.

In some demonstrative aspects, as shown in FIG. 2, the EMI shield connector 247 may include a snap configured to snap over the tube 238.

In some demonstrative aspects, as shown in FIG. 2, a shape of the snap of the EMI shield connector 247 may be configured to conform to a shape of the outer surface of the tube 238.

In one example, snap 247 may be configured as a single, continuous, snap element, which may be configured to extend along substantially an entire first side of the EMI shield lid 242, e.g., as described below.

In one example, snap 247 may be configured to include a plurality of snap elements, which may be configured to snap over different portions of the tube 238, e.g., as described below.

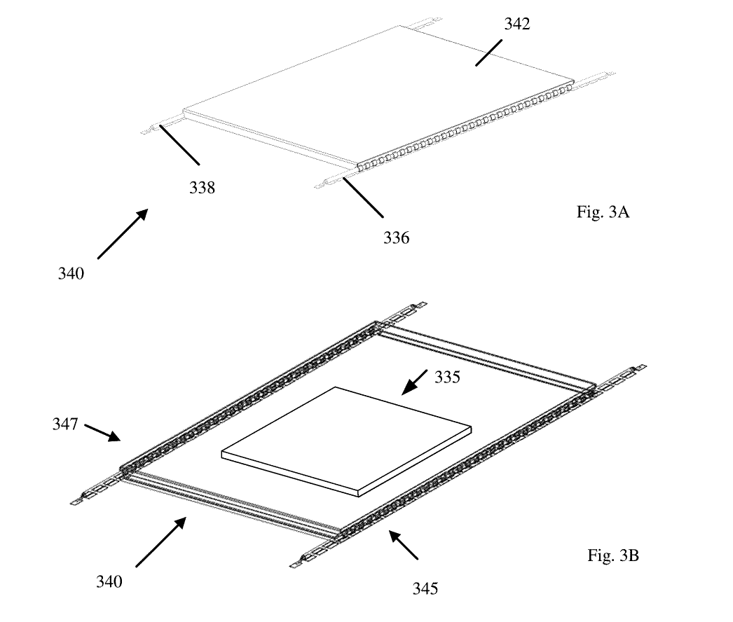

Reference is made to FIG. 3A, which schematically illustrates an EMI shield 340, and to FIG. 3B, which schematically illustrates the EMI shield 340, while excluding a lid of the EMI shield, to illustrate assembly of the EMI shield 340 on a PCB, in accordance with some demonstrative aspects. For example, EMI shield 140 (FIG. 1) may include one or more elements of EMI shield 340, and/or may perform one or more functionalities of EMI shield 340.

In some demonstrative aspects, EMI shield 340 may be configured to provide EMI shielding for electronic circuitry 335 on a PCB, e.g., PCB 130 (FIG. 1).

In some demonstrative aspects, as shown in FIGS. 3A and 3B, EMI shield 340 may include an EMI shield lid 342 configured to cover the electronic circuitry 335 on the PCB.

In some demonstrative aspects, as shown in FIGS. 3A and 3B, the EMI shield 340 may include a first EMI shield connector 345, which may be configured, for example, to detachably connect a first side of the EMI shield lid 342 to a tube 336 on the PCB, e.g., as described below.

In some demonstrative aspects, as shown in FIGS. 3A and 3B, EMI shield connector 345 may be configured to include a plurality of snaps along the first side of the EMI shield lid 342, for example, to snap over the tube 336, e.g., as described below.

In some demonstrative aspects, as shown in FIGS. 3A and 3B, the EMI shield 340 may include a second EMI shield connector 347, which may be configured, for example, to detachably connect a second side of the EMI shield lid 342 to a tube 338 on the PCB.

In some demonstrative aspects, as shown in FIGS. 3A and 3B, EMI shield connector 347 may be configured to include a plurality of snaps along the second side of the EMI shield lid 342, for example, to snap over the tube 338, e.g., as described below.

In some demonstrative aspects, the snaps of EMI shield connector 345 and/or the snaps of EMI shield connector 347 may be formed as part of EMI shield lid 342. For example, the snaps of EMI shield connector 345 and/or the snaps of EMI shield connector 347 may be formed by a suitable stamping process applied to the EMI shield lid 342.

In some demonstrative aspects, the snaps of EMI shield connector 345 and/or the snaps of EMI shield connector 347 may be formed by separate and/or dedicated snapping elements, which may be connected to the EMI shield lid 342. For example, the snaps of EMI shield connector 345 and/or the snaps of EMI shield connector 347 may be connected to the EMI shield lid 342 using spot welds, rivets, screws, and/or any other suitable mechanism and/or procedure.

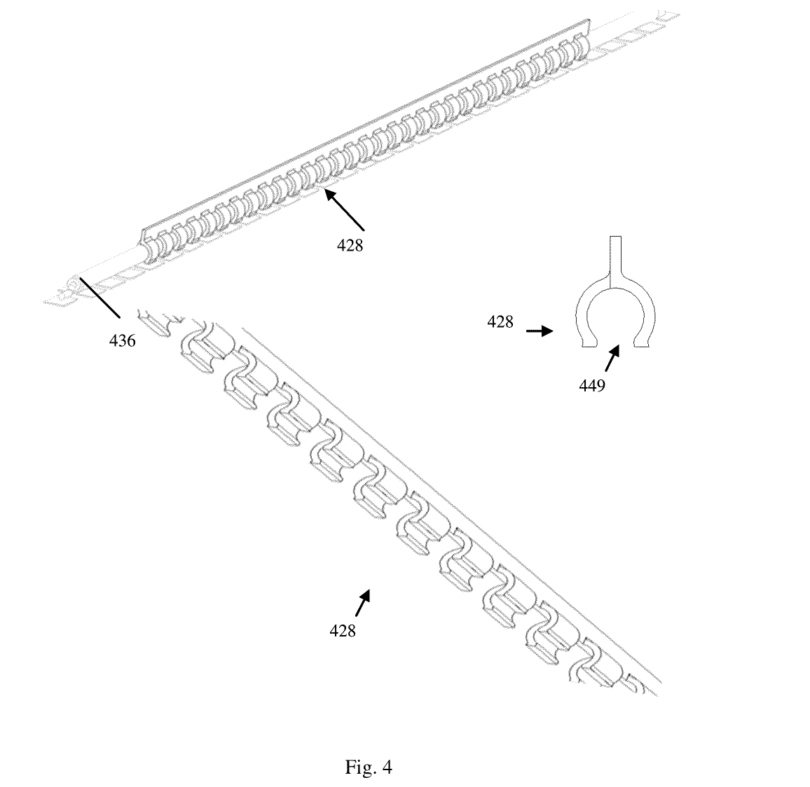

Reference is made to FIG. 4, which schematically illustrates a plurality of snaps 448 of an EMI connector, which may be configured to snap over a tube 436, in accordance with some demonstrative aspects. For example, EMI shield connector 345 (FIG. 3) and/or EMI shield connector 347 (FIG. 3) may include snaps 448.

In one example, tube 436 may include tube 336 (FIG. 3) or tube 338 (FIG. 3).

In some demonstrative aspects, as shown in FIG. 4, tube 436 may include a circular or cylindrical tube.

In some demonstrative aspects, as shown in FIG. 4, a shape of a snap 448 may be configured based on a shape of an outer surface of the tube 436.

In some demonstrative aspects, as shown in FIG. 4, the snap 448 may include a tube-engagement surface 449 configured to engage with an outer surface of the tube 436.

In some demonstrative aspects, as shown in FIG. 4, a shape of the tube-engagement surface 449 may be conform to a shape of the outer surface of the tube 436.

In some demonstrative aspects, as shown in FIG. 4, the shape of the tube-engagement surface 449 may include a generally circular shape, which may be configured based on the cylindrical shape of the outer surface of the tube 436.

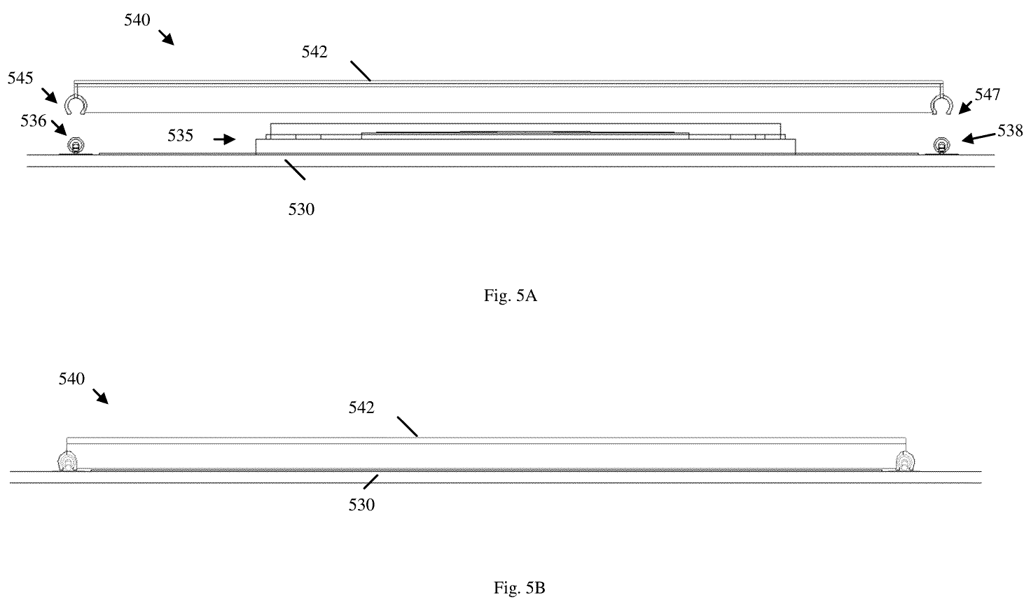

Reference is made to FIG. 5A, which schematically illustrates an EMI shield 540 at a detached state, and to FIG. 5B, which schematically illustrates the EMI shield 540 at an attached state, in accordance with some demonstrative aspects. For example, EMI shield 140 (FIG. 1) may include one or more elements of EMI shield 540, and/or may perform one or more functionalities of EMI shield 540.

In some demonstrative aspects, EMI shield 540 may be configured to provide EMI shielding for electronic circuitry 535 on a PCB 530.

In some demonstrative aspects, as shown in FIG. 5A, EMI shield 540 may include an EMI shield lid 542 configured to cover the electronic circuitry 535.

In some demonstrative aspects, as shown in FIG. 5A, the EMI shield 540 may include a first EMI shield connector 545 on a first side of the EMI shield lid 542, for example, to connect the EMI shield lid 542 to a tube 536 on the PCB 530.

In some demonstrative aspects, as shown in FIGS. 5A and 5B, EMI shield connector 545 may include a detachable connector, which may be configured to detachably connect the EMI shield lid 545 to the tube 536.

In some demonstrative aspects, as shown in FIG. 5A, the EMI shield 540 may include a second EMI shield connector 547 on a second side of the EMI shield lid 542, for example, to connect the EMI shield lid 542 to a second tube 538 on the PCB 530.

In some demonstrative aspects, as shown in FIGS. 5A and 5B, EMI shield connector 547 may include a detachable connector, which may be configured to detachably connect the EMI shield lid 547 to the tube 538.

In some demonstrative aspects, as shown in FIGS. 5A and 5B, a shape of EMI shield connector 545 may be configured to conform to a shape of the outer surface of the tube 536.

In some demonstrative aspects, as shown in FIGS. 5A and 5B, a shape of EMI shield connector 547 may be configured to conform to a shape of the outer surface of the tube 538.

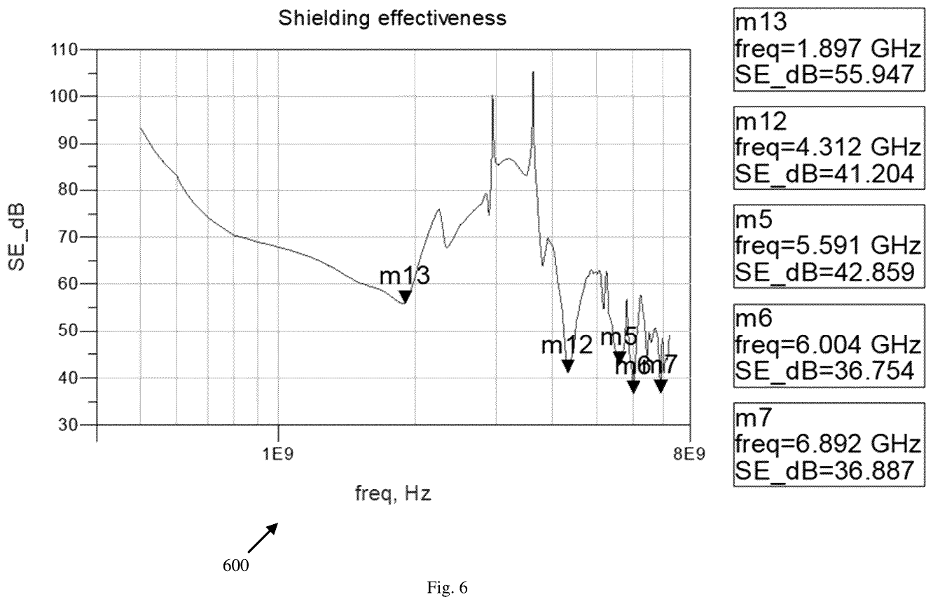

Reference is made to FIG. 6, which schematically illustrates a graph 600 depicting an EMI Shielding Effectiveness (SE) of an EMI shield versus frequency, in accordance with some demonstrative aspects.

In one example, graph 600 may depict simulation results of the SE of an EMI shield, e.g., EMI shield 140 (FIG. 1), utilizing one or more tubes as EMI shielding fences.

In some demonstrative aspects, as shown in FIG. 6, a relatively high SE may be achieved, for example, at frequencies up to 7.2 GHz.

In some demonstrative aspects, a SE greater than 36 dB may be achieved, for example, for frequencies lower than 7.2 GHz.

In some demonstrative aspects, as shown in FIG. 6, an EMI shield utilizing one or more tubes as EMI shielding fences may be effective for both broadband and narrow band interference.

In one example, as shown in FIG. 6, an SE of about 56 dB may be achieved at a frequency of 1.897 GHz.

In another example, as shown in FIG. 6, an SE of about 43 dB may be achieved at frequency of 5.591 GHz.

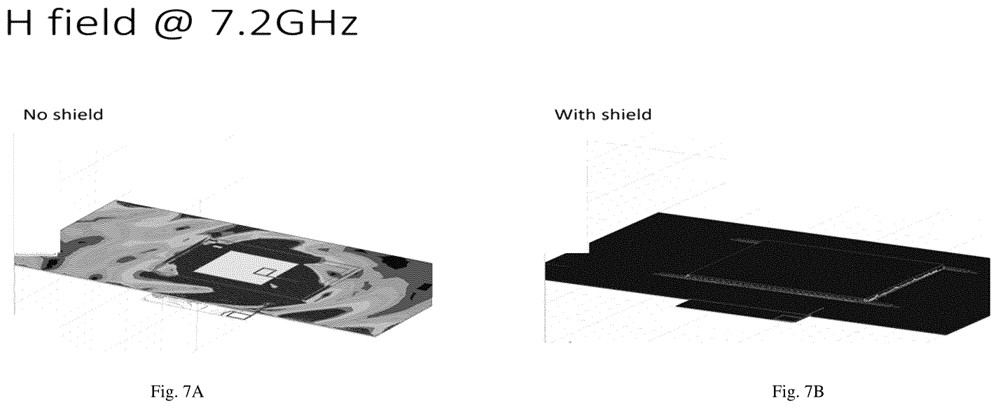

Reference is made to FIG. 7A, which schematically illustrates a magnetic field (H-field) of electronic circuity, and to FIG. 7B, which schematically illustrates the H-field of the electronic circuity when implementing an EMI shield, in accordance with some demonstrative aspects.

In one example, the graph of FIG. 7B may be based on simulation results of the H-field of electronic circuitry 135 (FIG. 1), for example, when using EMI shield 140 (FIG. 1) to provide EMI shielding for electronic circuitry 135 (FIG. 1), e.g., at a frequency of 7.2 GHz.

In some demonstrative aspects, as shown in FIG. 7B, EMI shield 140 (FIG. 1) may provide relatively high SE for EMI/RFI of the H-field at the frequency of 7.2 GHz.

In some demonstrative aspects, EMI shield connectors 145 and/or 147 (FIG. 1) may be configured to provide proper grounding, for example, to achieve the required shielding effectiveness at frequencies of interest, e.g., up to 7.2 GHz and/or any other frequencies.

In some demonstrative aspects, as shown in FIG. 7B, EMI shield 140 (FIG. 1) may provide effective EMI shielding for the H-field, for example, near the sides of the electronic circuitry, e.g., close to where EMI shield connectors 145 and/or 147 (FIG. 1) are located.

In some demonstrative aspects, as shown in FIG. 7A, there may be noise leaks on top and bottom ends of the PCB.

In some demonstrative aspects, as shown in FIG. 7B, EMI shield 140 (FIG. 1) may provide effective EMI shielding, which may minimize noise coupling at an antenna area, which may be located close to the shielded area.

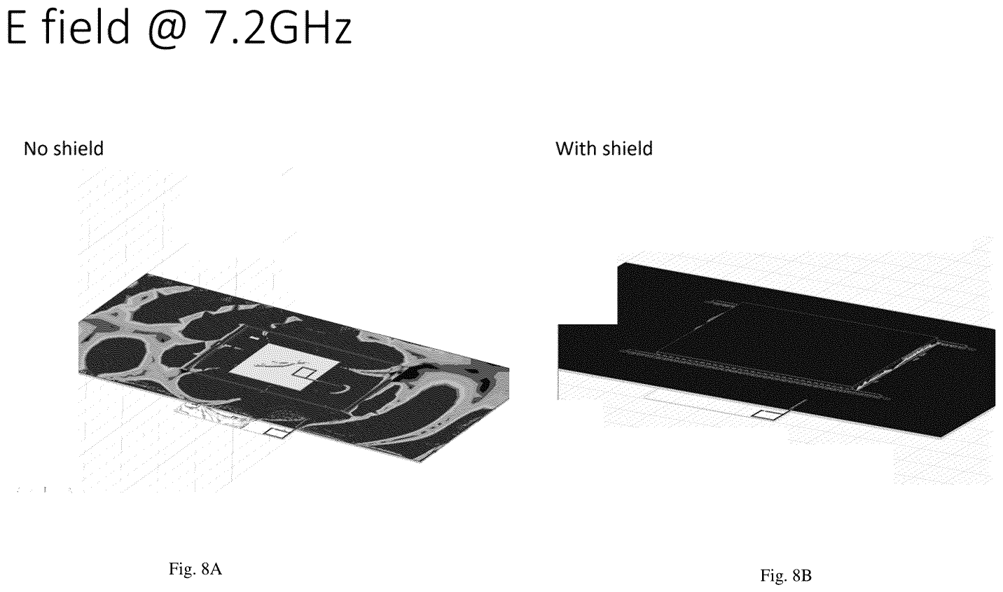

Reference is made to FIG. 8A, which schematically illustrates an Electric field (E-field) of electronic circuity, and to FIG. 8B, which schematically illustrates the E-field of the electronic circuity when implementing an EMI shield, in accordance with some demonstrative aspects.

In one example, the graph of FIG. 8B may be based on simulation results of the E-field of electronic circuitry 135 (FIG. 1), for example, when using EMI shield 140 (FIG. 1) to provide EMI shielding for electronic circuitry 135 (FIG. 1), e.g., at a frequency of 7.2 GHz.

In some demonstrative aspects, as shown in FIG. 8B, EMI shield 140 (FIG. 1) may provide relatively high SE for EMI/RFI of the E-field at the frequency of 7.2 GHz.

In some demonstrative aspects, EMI shield connectors 145 and/or 147 (FIG. 1) may be configured to provide proper grounding, for example, to achieve the required shielding effectiveness at frequencies of interest, e.g., up to 7.2 GHz and/or any other frequencies.

In some demonstrative aspects, as shown in FIG. 8B, EMI shield 140 (FIG. 1) may provide effective EMI shielding for the E-field, for example, near the sides of the electronic circuitry, e.g., close to where EMI shield connectors 145 and/or 147 (FIG. 1) are located.

In some demonstrative aspects, as shown in FIG. 8A, there may be noise leaks on top and bottom ends of the PCB.

In some demonstrative aspects, as shown in FIG. 8B, EMI shield 140 (FIG. 1) may provide effective EMI shielding, which may minimize the noise coupling at an antenna area, which may be located close to the shielded area.

### EXAMPLES

The following examples pertain to further aspects.

Example 1 includes an apparatus comprising an Electromagnetic Interference (EMI) shield configured to provide EMI shielding for electronic circuitry on a Printed Circuit Board (PCB), the EMI shield comprising an EMI shield lid configured to cover the electronic circuitry on the PCB; and an EMI shield connector configured to connect the EMI shield lid to at least one tube on the PCB, wherein the EMI shield connector is configured to ground the EMI shield lid via the tube.

For example, the EMI shield may be configured to include an EMI shield lid; and an EMI shield connector to electrically couple the EMI shield lid to at least one tube on the PCB, for example, to provide a ground to the EMI shield lid via the at least one tube. For example, the EMI shield connector may be configured to maintain the EMI shield lid over the electronic circuitry on the PCB.

Example 2 includes the subject matter of Example 1, and optionally, wherein the EMI shield connector is configured to form with the at least one tube an EMI shield fence between the EMI shield lid and the PCB.

For example, the EMI shield may include an EMI shield fence disposed between the EMI shield lid and the PCB. For example, the EMI shield fence may be formed with the EMI shield connector and the at least one tube.

Example 3 includes the subject matter of Example 2, and optionally, wherein the EMI shield connector is configured to form the EMI shield fence along at least one side of the EMI shield lid.

For example, the EMI shield fence may be formed along at least one side of the EMI shield lid with the EMI shield connector.

Example 4 includes the subject matter of any one of Examples 1-3, and optionally, wherein the EMI shield connector is configured to provide a ground to the EMI shield lid, e.g., to ground the EMI shield lid, via a solder between the tube and the PCB.

Example 5 includes the subject matter of any one of Examples 1-4, and optionally, wherein the EMI shield connector comprises at least one snap configured to snap over the tube.

Example 6 includes the subject matter of Example 5, and optionally, wherein the snap comprises a tube-engagement surface configured to engage and/or capable of engaging with an outer surface of the tube, wherein a shape of the tube-engagement surface is configured based on a shape of the outer surface of the tube. For example, the tube-engagement surface nay include a shape based on a shape of the outer surface of the at least one tube.

Example 7 includes the subject matter of Example 5 or 6, and optionally, wherein the at least one snap comprises a plurality of snaps along at least one side of the EMI shield lid.

Example 8 includes the subject matter of Example 7, and optionally, wherein a distance between two adjacent snaps of the plurality of snaps is less than 1.2 millimeter.

Example 9 includes the subject matter of any one of Examples 1-8, and optionally, wherein a shape of the EMI shield connector is configured based on a shape of an outer surface of the tube. For example, the EMI shield connector may include a shape based on a shape of an outer surface of the at least one tube.

Example 10 includes the subject matter of any one of Examples 1-9, and optionally, wherein the EMI shield connector extends along at least one side of the EMI shield lid.

Example 11 includes the subject matter of any one of Examples 1-10, and optionally, wherein the EMI shield comprises a first EMI shield connector on a first side of the EMI shield lid to connect and/or electrically couple the EMI shield lid to a first tube on the PCB, and a second EMI shield connector on a second side of the EMI shield lid to connect and/or electrically couple the EMI shield lid to a second tube on the PCB.

Example 12 includes the subject matter of Example 11, and optionally, wherein the first side is opposite to the second side.

Example 13 includes the subject matter of any one of Examples 1-12, and optionally, wherein the EMI shield connector comprises a detachable connector configured to detachably connect the EMI shield lid to the tube and/or to and/or electrically decouple the EMI shield lid from the tube.

Example 14 includes the subject matter of any one of Examples 1-13, and optionally, wherein the EMI shield is configured to provide the EMI shielding to at least frequencies in a frequency range between about 2.4 Gigahertz (GHz) and about 7.2 GHz.

Example 15 includes the subject matter of any one of Examples 1-14, and optionally, wherein the EMI shield is configured to provide the EMI shielding at frequencies up to at least about 2.4 Gigahertz.

Example 16 includes the subject matter of any one of Examples 1-15, and optionally, comprising the PCB.

Example 17 includes an electronic device comprising a Printed Circuit Board (PCB); electronic circuitry on the PCB; at least one tube soldered to the PCB; and an Electromagnetic Interference (EMI) shield configured to provide EMI shielding for the electronic circuitry on the PCB, the EMI shield comprising an EMI shield lid disposed over the electronic circuitry on the PCB and/or configured to cover the electronic circuitry on the PCB; and an EMI shield connector configured to connect the EMI shield lid to the at least one tube on the PCB, wherein the EMI shield connector is configured to ground the EMI shield lid via a solder between the tube and the PCB.

For example, the EMI shield connector may be configured to electrically couple the EMI shield lid to the at least one tube on the PCB to provide a ground to the EMI shield lid via the at least one tube.

Example 18 includes the subject matter of Example 17 and optionally, implementing one or more additional elements, aspects, and/or functionalities, for example, as described with respect to Examples 1-16.

Example 19 includes a computing device comprising a display; a processor; a memory; a Printed Circuit Board (PCB); electronic circuitry on the PCB; at least one tube soldered to the PCB; and an Electromagnetic Interference (EMI) shield configured to provide EMI shielding for the electronic circuitry on the PCB, the EMI shield comprising an EMI shield lid disposed over the electronic circuitry on the PCB and/or configured to cover the electronic circuitry on the PCB; and an EMI shield connector configured to connect the EMI shield lid to the at least one tube on the PCB, wherein the EMI shield connector is configured to ground the EMI shield lid via a solder between the tube and the PCB.

For example, the EMI shield connector may be configured to electrically couple the EMI shield lid to the at least one tube on the PCB to provide a ground to the EMI shield lid via the at least one tube.

Example 20 includes the subject matter of Example 19 and optionally, implementing one or more additional elements, aspects, and/or functionalities, for example, as described with respect to Examples 1-16.

Example 21 includes an apparatus comprising means for performing any of the described operations and/or functionalities of Examples 1-16.

Example 22 includes a method including any of the described operations and/or functionalities of Examples 1-16.

Functions, operations, components and/or features described herein with reference to one or more aspects, may be combined with, or may be utilized in combination with, one or more other functions, operations, components and/or features described herein with reference to one or more other aspects, or vice versa.

While certain features have been illustrated and described herein, many modifications, substitutions, changes, and equivalents may occur to those skilled in the art. It is, therefore, to be understood that the appended claims are intended to cover all such modifications and changes as fall within the true spirit of the disclosure.

What is claimed is:

1. An apparatus comprising:
an Electromagnetic Interference (EMI) shield configured to provide EMI shielding for electronic circuitry on a Printed Circuit Board (PCB), the EMI shield comprising:
an EMI shield lid; and
an EMI shield connector to electrically couple the EMI shield lid to at least one tube on the PCB to provide a ground to the EMI shield lid via the at least one tube, wherein the EMI shield connector is configured to maintain the EMI shield lid over the electronic circuitry on the PCB.

2. The apparatus of claim 1, wherein the EMI shield connector is configured to form with the at least one tube an EMI shield fence between the EMI shield lid and the PCB.

3. The apparatus of claim 2, wherein the EMI shield connector is configured to form the EMI shield fence along at least one side of the EMI shield lid.

4. The apparatus of claim 1, wherein the EMI shield connector is configured to provide the ground to the EMI shield lid via a solder between the at least one tube and the PCB.

5. The apparatus of claim 1, wherein the EMI shield connector comprises at least one snap configured to snap over the at least one tube.

6. The apparatus of claim 5, wherein the snap comprises a tube-engagement surface capable of engaging with an outer surface of the at least one tube, wherein the tube-engagement surface comprises a shape based on a shape of the outer surface of the at least one tube.

7. The apparatus of claim 5, wherein the at least one snap comprises a plurality of snaps along at least one side of the EMI shield lid.

8. The apparatus of claim 7, wherein a distance between two adjacent snaps of the plurality of snaps is less than 1.2 millimeter.

9. The apparatus of claim 1, wherein the EMI shield connector comprises a shape based on a shape of an outer surface of the at least one tube.

10. The apparatus of claim 1, wherein the EMI shield connector extends along at least one side of the EMI shield lid.

11. The apparatus of claim 1, wherein the EMI shield comprises a first EMI shield connector on a first side of the EMI shield lid to electrically couple the EMI shield lid to a first tube on the PCB, and a second EMI shield connector on a second side of the EMI shield lid to electrically couple the EMI shield lid to a second tube on the PCB.

12. The apparatus of claim 11, wherein the first side is opposite to the second side.

13. The apparatus of claim 1, wherein the EMI shield connector comprises a detachable connector configured to detachably couple the EMI shield lid to the at least one tube.

14. The apparatus of claim 1, wherein the EMI shield provides the EMI shielding to at least frequencies in a frequency range between about 2.4 Gigahertz (GHz) and about 7.2 GHz.

15. The apparatus of claim 1, wherein the EMI shield provides the EMI shielding at frequencies up to at least about 2.4 Gigahertz.

16. The apparatus of claim 1 comprising the PCB.

17. An electronic device comprising:
a Printed Circuit Board (PCB);
electronic circuitry on the PCB;
at least one tube soldered to the PCB; and
an Electromagnetic Interference (EMI) shield configured to provide EMI shielding for the electronic circuitry on the PCB, the EMI shield comprising:
an EMI shield lid disposed over the electronic circuitry on the PCB; and
an EMI shield connector configured to electrically couple the EMI shield lid to the at least one tube on the PCB to provide a ground to the EMI shield lid via the at least one tube.

18. The electronic device of claim 17 comprising an EMI shield fence between the EMI shield lid and the PCB, wherein the EMI shield fence is formed with the EMI shield connector and the at least one tube.

19. A computing device comprising:
a display;
a processor;
a memory;
a Printed Circuit Board (PCB);
electronic circuitry on the PCB;
at least one tube soldered to the PCB; and
an Electromagnetic Interference (EMI) shield configured to provide EMI shielding for the electronic circuitry on the PCB, the EMI shield comprising:
an EMI shield lid disposed over the electronic circuitry on the PCB; and
an EMI shield connector configured to electrically couple the EMI shield lid to the at least one tube on the PCB to provide a ground to the EMI shield lid via the at least one tube.

20. The computing device of claim 19, wherein the EMI shield connector comprises a detachable connector configured to detachably couple the EMI shield lid to the at least one tube.
